(19) United States
(12) Patent Application Publication
(10) Pub. No.: US 2026/0013323 A1
(43) Pub. Date: Jan. 8, 2026

(54) AN ORGANIC ELECTRIC ELEMENT COMPRISING A METAL PATTERNING LAYER AND AN ELECTRONIC DEVICE THEROF

(71) Applicant: DUK SAN NEOLUX CO., LTD., Cheonan-si, Chungcheongnam-do (KR)

(72) Inventors: Kyung Hwan OH, Cheonan-si, Chungcheongnam-do (KR); Jung Geun LEE, Cheonan-si, Chungcheongnam-do (KR); Jae Duk YOO, Cheonan-si, Chungcheongnam-do (KR); Sun Hee LEE, Cheonan-si, Chungcheongnam-do (KR); Won Joan CHEONG, Cheonan-si, Chungcheongnam-do (KR)

(73) Assignee: DUK SAN NEOLUX CO., LTD., Cheonan-si, Chungcheongnam-do (KR)

(21) Appl. No.: 18/881,547

(22) PCT Filed: Jun. 16, 2023
(86) PCT No.: PCT/KR2023/008342

§ 371 Date: Jan. 6, 2025

(30) Foreign Application Priority Data
Jul. 6, 2022 (KR) 10-2022-0083362

(51) Int. Cl. H10K 50/813

(52) U.S. Cl. CPC H10K 50/813

(57) ABSTRACT

The present invention provides an organic electric element including a metal patterning layer formed on the outside of a metal electrode and an electronic device thereof, and by forming a patterning auxiliary photosensitive layer made of a material with excellent photosensitivity under the metal patterning layer, it is possible to easily measure the thickness of the metal patterning layer.

### TECHNICAL FIELD

The present invention relates to an organic electric element including a metal patterning layer and an electronic device thereof, and more specifically, to an organic electric element and an electronic device thereof, which facilitates thickness measurement of a metal patterning layer by forming a patterning auxiliary photosensitive layer under the metal patterning layer.

### BACKGROUND ART

Due to the continuous advancement of display technology, user demands for display devices are increasing, and terminal display devices are being developed in the direction of flexibility, full screen, and high integration.

For smartphone displays, the bezel sizes is being reduced, or bezel-less under-display technology is being developed to increase screen size. During this process, physical buttons on the front of smartphones have disappeared into the screen, or technologies such as UDC (Under Display Camera) or UPS (Under Panel Sensor) have been developed.

The UDC camera can operate normally only when high light transmittance of the display must be ensured. Accordingly, smartphones or electronic devices applying technologies such as UDC need to secure high light transmittance. Korean Registered Patent No. 10-2324529, filed by the present applicant, discloses that this can be achieved by forming a metal patterning layer.

Additionally, Korean Patent Publication No. 10-2022-0006001 discloses a metal patterning method employing an organic thin film that forms an organic patterning layer by a vacuum deposition method and selectively repels a metal material.

It is important that this metal patterning layer or organic patterning layer (hereinafter referred to as a metal patterning layer) is formed with an appropriate thickness to ensure light transmittance. If the metal patterning layer is too thick, transmittance may decrease due to aggregation phenomena, and the surface may become uneven, and thus it is difficult to deposit additional thin film on top of the aggregated thin film.

Therefore, it is important to control the thickness of the metal patterning layer to realize a high-quality transparent display with high transmittance, and to control the thickness of the metal patterning layer, it must be possible to measure its thickness easily and accurately.

In general, a method for checking the thickness of a thin film in the display manufacturing process is to utilize the photoluminescence (PL) characteristic among the optical properties of the compound forming the thin film.

However, since the material formed on the metal patterning layer has low photoluminescence characteristics in the visible light range, it is difficult to measure the thickness of the metal patterning layer using an optical method, such as an ellipsometer. Therefore, in order to measure the thickness of the metal patterning layer, a scanning electron microscope (SEM) must be used. However, it is practically very difficult to check the thin film thickness using a scanning electron microscope every time during the display manufacturing process.

Therefore, it is necessary to develop a technology for an organic electric element including a metal patterning layer that allows the thickness of the metal patterning layer to be easily measured using conventional optical methods while ensuring a certain level of accuracy.

### Prior Art Documents

Korean Registered Patent No. 10-2324529

Korean Published Patent No. 10-2022-0006001

### DETAILED DESCRIPTION OF THE INVENTION

### Technical Challenge

Accordingly, the purpose of the present invention is to provide an organic electric element and an electronic device thereof capable of easily measuring the thickness of a metal patterning layer while satisfying the required characteristics of a display, particularly a transparent display using the photoluminescence characteristics by introducing a patterning auxiliary photosensitive layer, wherein the patterning auxiliary photosensitive layer is formed of a material having excellent photoluminescence characteristics between a metal patterning layer and an organic material layer.

### Means of Solving Problems

In one aspect, the present invention provides an organic electric element including a metal patterning layer formed on the outside of a metal electrode and a patterning auxiliary photosensitive layer formed under the metal patterning layer, wherein the patterning auxiliary photosensitive layer is formed of a photosensitive organic material having a stronger intensity of photoluminescence than the metal patterning layer.

In another aspect, the present invention provides an electronic device including a display device including the organic electric element and a control unit for driving the display device.

### Effect of Invention

According to the present invention, by introducing a patterning auxiliary photosensitive layer formed of a material having excellent photoluminescence characteristics between a metal patterning layer and an organic material layer, the thickness of the metal patterning layer can be easily and with a certain degree of accuracy measured, and an organic electric element and an electronic device thereof which can satisfy the characteristics required for a display, particularly a transparent display, can be provided.

### BRIEF DESCRIPTION OF THE DRAWINGS

FIG. 1 illustrates an example of a laminated structure of an organic electric element according to one embodiment of the present invention.

FIG. 2 is a cross-sectional view taken along line A-A′ in FIG. 1.

FIG. 3 illustrates an example of a laminated structure of an organic electric element according to another embodiment of the present invention.

FIG. 4 illustrates an example of a laminated structure of an organic electric element according to another embodiment of the present invention.

FIG. 5 is a drawing for explaining a method for manufacturing an organic electric element according to one embodiment of the present invention.

FIGS. 6 to 10 are graphs showing the photoluminescence intensity measured according to the wavelength of samples manufactured according to Examples 1 to 5, respectively.

FIGS. 11 to 14 are photographs of the surfaces of samples of Comparative Examples 1 to 4, respectively, taken using an electron microscope.

FIG. 15 is a SEM cross-sectional view of the sample of Example 5.

FIG. 16 is a graph showing the light transmittance measured for the sample of Example 6.

FIG. 17 is a graph showing the light transmittance measured for the sample of Comparative Example 5.

FIG. 18 is a graph showing the light transmittance measured for the sample of Comparative Example 6.

[Description of Reference Numerals]

| | |
|---|---|
| 100, 200, 300: organic electric | 110: first electrode |
| element | |
| 120: hole injection layer | 130: hole transport layer |
| 140: light-emitting layer | 150: electron transport layer |
| 180: light efficiency improving layer | 210: first portion |
| 212: metal patterning layer | 214: patterning auxiliary |
| | photosensitive layer |
| 220: second portion | 222: second electrode |
| 224: electron injection layer | 320: first hole injection layer |
| 330: first hole transport layer | 340: first light-emitting layer |
| 350: first electron transport layer | 360: first charge generation |
| | layer |
| 361: second charge generation layer | 420: second hole injection layer |
| 430: second hole transport layer | 440: second light-emitting layer |
| 450: second electron transport layer | CGL: charge generation layer |
| ST1: first stack | ST2: second stack |

### DETAILED DESCRIPTION

Hereinafter, embodiments of the present invention will be described in detail with reference to the attached figures.

In assigning reference numerals to the components of each figures, it should be noted that the same components are given the same reference numerals as much as possible, even if they are shown in different figures. Furthermore, in describing the present invention, detailed explanations of related known structures or functions may be omitted when it may make the subject matter of the present invention rather unclear.

Terms, such as first, second, A, B, (a), (b) or the like may be used herein when describing components of the present invention. Each of these terminologies is not used for defining an essence, order or sequence of a corresponding component but used merely to distinguish the corresponding component from other component(s). It will be understood that the expression ‘one component is “connected,” “coupled” or “joined” to another component’ comprises the case where a third component may be “connected,” “coupled” or “joined” between one component and another component as well as the case where the first component may be directly connected, coupled or joined to the second component.

In addition, when a component such as a layer, film, region, or substrate is described as being “on” or “over” another component, it should be understood to include not only cases where it is “directly on” the other component but also cases where another component is interposed between them.

In addition, when a component such as a layer, film, region, or substrate is described as being “formed on” or “over” another component, it should be understood to include not only cases where it is formed on the entire upper surface but also cases where it is formed on at least a part of the upper surface of the other component.

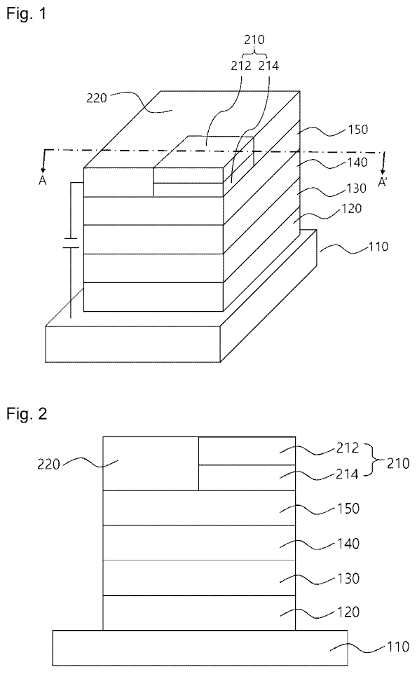

Hereinafter, the organic electric element according to embodiments of the present invention will be described in detail with reference to the accompanying FIGS. 1 and 2.

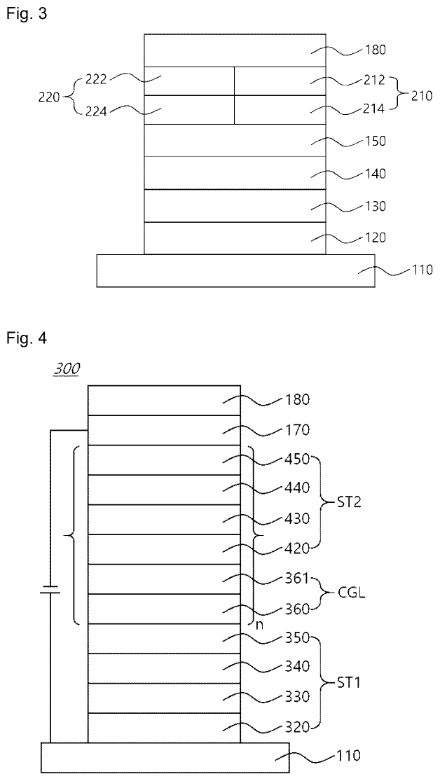

FIGS. 1 and 2 schematically illustrate the structure of an organic electric element according to one embodiment of the present invention, and FIG. 2 is a cross-sectional view taken along line A-A′ in FIG. 1. FIG. 3 schematically illustrates the structure of an organic electric element according to another embodiment of the present invention.

Referring to FIGS. 1 to 3, the organic electric element according to one embodiment of the present invention includes, a first electrode 110, an organic material layer on the first electrode, and a first portion 210 and a second portion 220 on the organic material layer, and these are sequentially arranged on a substrate (not shown).

The first electrode 110 is an anode (positive electrode) and may be a reflective electrode, a semi-transmissive electrode, or a transmissive electrode. Typically, materials used to form a transmissive cathode may be selected from transparent conductive oxides (TCOs), for example, from indium tin oxide (ITO), zinc oxide (ZnO), tin oxide (SnO2), or indium zinc oxide (IZO), and combinations thereof, but are not limited thereto.

Materials for forming a semi-transmissive electrode or reflective electrode may be selected from, for example, magnesium (Mg), silver (Ag), aluminum (AI), lithium (Li), calcium (Ca), indium (In), and combinations thereof, but are not limited to these.

Additionally, the first electrode 110 may also be used as an anode for a multilayer that includes two or more layers of TCO and/or a metal thin film.

The organic material layer may consist of multiple layers containing an organic compound and may also include an inorganic compound.

The organic material layer includes a hole transport region, an light-emitting layer 140 and an electron transport region, and the hole transport region may include a hole injection layer 120 and a hole transport layer 130, and the electron transport region may include an electron transport layer 150. The hole transport region may further include an emission auxiliary layer, an electron blocking layer, and the like, while the electron transport region may additionally include an electron transport auxiliary layer, a hole blocking layer, a buffer layer, and the like.

The hole injection layer 120, hole transport layer 130, electron blocking layer, and emission auxiliary layer may be formed from any materials commonly used as hole injection/transport materials, for example, aromatic or heteroaromatic amine compounds and carbazole derivatives, specifically, may be selected from materials consisting of NATA, 2T-NATA, NPNPB, F4-TCNQ, PPDN, TPD (N,N′-bis-(3-methylphenyl)-N, N′-bis-(phenyl)-benzidine), PPD, TTBND, FFD, p-dmDPS, TAPC, TCTA, PTDATA, TDAPB, TDBA, 4-a, Spiro-TPD, Spiro-mTTB, spiro-2, NPD (N,N-dinaphthyl-N, N′-diphenyl benzidine), s-TAD, and MTDATA (4,4′,4″-tris(N-3-methylphenyl-N-phenyl-amino)-triphenylamine), but there is not limited to these.

The light-emitting layer 140 may include a host and a dopant. The host may be selected from any materials commonly used as hosts, such as aromatic or heteroaromatic amine compounds, azine compounds, and fused polycyclic aromatic compounds, but is not limited to these. The dopant may include any materials commonly used as dopants, such as fluorescent or phosphorescent luminescent compounds, for example, it may be selected from fused polycyclic aromatic compounds, metal complexes of iridium (Ir), osmium (Os), platinum (Pt), and the like, but is not limited to these.

The electron transport layer 150, buffer layer, and electron transport auxiliary layer can typically be formed from any materials commonly used as electron injection/transport materials. For example, materials of the electron transport layer and buffer layer may be selected from heteroaromatic compounds such as azine derivatives, carbazole derivatives, phenanthroline derivatives, imidazole derivatives, benzimidazole derivatives, and benzoxazole derivatives, or metal complexes such as aluminum (Al) complexes and zinc (Zn) complexes, but there is not limited to these.

On the organic material layer, a first portion 210 and a second portion 220 are formed, wherein the second portion 220 is formed on at least a part of the upper surface of the organic material layer where the first portion 210 is not formed. In FIGS. 1 and 2, the surfaces of the first portion and the second portion are depicted as having the same height, however, their heights may be the same or different. Additionally, FIGS. 1 and 2 are the simplified illustrations for explaining the laminated structure of the organic electric element, wherein the height, area, and positions of the first portion and the second portion are not limited by these figures.

The first portion 210 is a non-emissive region and includes a metal patterning layer 212 and a patterning auxiliary photosensitive layer 214, while the second portion 220 is an emissive region and includes a second electrode which is a metal electrode. Therefore, the first portion 210 may be a light-transmitting part, and the second portion 220 may be a non-light-transmitting part.

The second portion 220 cannot secure the light transmittance required in the electroluminescence region, transparent displays, UDC/UPS, etc. since the second portion 220, which includes a second electrode, is formed of a metal material. In organic electric elements applied to such electronic devices, it is necessary to form region where electroluminescence does not occur but have high optical transmittance since the outer side of the second electrode on top of the organic material layer is not formed of a metallic material. That is, it is necessary to form a metal patterning layer in order to suppress the formation of metal material.

The metal patterning layer 212 is arranged on the outside of the metal electrode, which is the second electrode, and the patterning auxiliary photosensitive layer 214 is formed on the lower side of the metal patterning layer 212. Preferably, the patterning auxiliary photosensitive layer 214 is also arranged on the outside of the metal electrode.

The metal patterning layer 212 may be formed of an organic material that suppresses the formation of a metal or a second electrode on the metal patterning layer, thereby preventing the metal or the second electrode from being formed in a very small amount or not being formed at all. For example, the metal patterning layer 212 may be formed from a compound selected from PBD(2-(4-biphenylyl)-5-phenyl-1,3,4-oxadiazole), PBD₂(2-([1,1′-biphenyl]-4-yl)-5-phenyl-1,3,4-oxadiazole), mCP(1,3-Bis(N-carbazolyl)benzene), TAZ(3-(4-Biphenyl)-4-phenyl-5-tert-butylphenyl-1,2,4-triazole), β-NPB (N,N′-Bis(naphthalen-2-yl)-N, N′-bis(phenyl)-benzidine), NTAZ (4-(Naphthalen-1-yl)-3,5-diphenyl-4H-1,2,4-triazole), tBUP-TAZ(3,5-bis(4-(tert-butyl) phenyl)-4-phenyl-4H-1,2,4-triazole), BND(2,5-(binaphth-1-yl)-1,3,4-oxadiazole), TBADN(2-tert-Butyl-9,10-di(naphth-2-yl)anthracene), CBP(4,4′-Bis(carbazol-9-yl) biphenyl), BAlq(Bis(2-methyl-8-quinolinolate)-4-(phenylphenolato)aluminium), m-BPC (9-([1,1′-biphenyl]-3-yl)-9H-carbazole), Ir(ppy)₃ (tris(2-phenylpyridine iridium(III)) and compounds containing fluorine (F) within their molecular structure, but is not limited thereto. Here, the organic material may include inorganic materials such as metals. Preferably, the metal patterning layer 212 may be formed from a compound containing fluorine within its molecular structure.

It is difficult to measure the thickness of the metal patterning layer using the photoluminescence properties since the material currently applied to the metal patterning layer 212 has no or very weak photoluminescence properties. If the thickness of the metal patterning layer 212 is too thick, coagulation occurs, making it difficult to form a uniform thin film on the surface of the metal patterning layer. As a result, it is difficult to secure uniform light transmittance, and there is a problem when additionally forming a thin film such as a light efficiency improvement layer.

Therefore, the present invention generally forms a patterning auxiliary photosensitive layer 214 with excellent photoluminescence characteristics under the metal patterning layer 212 to easily measure the thickness of the metal patterning layer 212 using optical characteristics. FIGS. 1 and 2 roughly illustrate a metal patterning layer 212 and a patterning auxiliary photosensitive layer 214. The positions where they are formed and their shapes may vary depending on the organic electric element to which they are applied, and the thicknesses of each of these layers may also differ. Therefore, the shapes, thicknesses, and formation positions of the metal patterning layer 212 and the patterning auxiliary photosensitive layer 214 are not limited by FIGS. 1 and 2.

The patterning auxiliary photosensitive layer 214 is formed from a photosensitive organic material that exhibits stronger photoluminescence intensity than the metal patterning layer 212 and possesses optical properties measurable by optical methods. Therefore, the material forming the patterning auxiliary photosensitive layer 214 may be a photosensitive organic material having a photoluminescence intensity stronger than that of the metal patterning layer 212 in the visible light range and exhibiting photoluminescence characteristics sufficient to enable measurement of the thickness of the thin film using an ellipsometer.

Preferably, the patterning auxiliary photosensitive layer 214 may include a compound including at least one heterocycle.

The heterocycle may be a C₂-C₆₀ heterocycle containing at least one heteroatom of O, N, S, Si and P, more preferably a C₂-C₃₀ heterocycle, and even more preferably a C₂-C₂₄ heterocycle, specifically, oxazole, thiazole, benzoxazole, benzothiazole, pyridine, pyrimidine, pyrazine, triazine, quinoline, quinazoline, quinoxaline, imidazole, triazole, benzimidazole, benzotriazole, furan, thiophene, benzofuran, benzothiophene, indole, dibenzofuran, dibenzothiophene, carbazole, benzofuropyridine, benzothienopyridine, carboline, benzofuropyrimidine, benzothienopyrimidine, benzofuropyrazine, and benzothienopyrazine, but is not limited to these.

The thickness of the patterning auxiliary photosensitive layer 214 is preferably 5 nm or more.

In addition, the patterning auxiliary photosensitive layer 214 is preferably formed using a vacuum deposition method. Therefore, in order to form the patterning auxiliary photosensitive layer 214, the molecular weight of the compound may be 1,500 g/mol or less, preferably 1,300 g/mol or less, more preferably 1,100 g/mol or less, and most preferably 1,000 g/mol or less. This is because it is difficult to form a thin film using a vacuum deposition method when the molecular weight of the compound forming the patterning auxiliary photosensitive layer 214 exceeds 1,500 g/mol.

The first portion 210 including the metal patterning layer 212 and the patterning auxiliary photosensitive layer 214 is a non-luminous region and may have a transmittance of 50% or more, preferably 70% or more, and more preferably 90% or more in the visible light region.

The second portion 220 formed on the organic material layer is a light-emitting region formed of metal and includes a second electrode, which is a metal electrode (cathode). In addition, the second portion 220 may include an electron injection layer. The electron injection layer may be formed or omitted as needed, and may be formed on the electron transport layer as needed. FIGS. 1 and 2 illustrate a case where the electron injection layer made of a metal material is not formed and the metal electrode corresponds to the second portion 220.

The second electrode 222 may be formed of a material having high electrical conductivity, such as, but not limited to, a material selected from silver (Ag), magnesium (Mg), aluminum (AI), ytterbium (Yb), copper (Cu), zinc (Zn), cadmium (Cd), gold (Au), nickel (Ni), cobalt (Co), iron (Fe), molybdenum (Mo), niobium (Nb), palladium (Pd), platinum (Pt), lithium (Li), sodium (Na), calcium (Ca), and combinations thereof.

According to another embodiment of the present invention, the organic electric element may further include at least one of an electron injection layer and a light efficiency improvement layer.

FIG. 3 illustrates a schematic laminated structure of an organic electric element according to another embodiment of the present invention.

Referring to FIG. 3, there is a difference from FIG. 2 in that an electron injection layer 224 is additionally included in the second portion 220, and a light efficiency improvement layer 180 is formed on the first portion 210 and the second portion 220. The electron injection layer 224 and the light efficiency improvement layer 180 may be formed or omitted as needed.

The electron injection layer 224 formed on the electron transport layer 150 is formed of metal. Therefore, when the electron injection layer 224 is deposited after the metal patterning layer 212 is formed, almost no metal is deposited on the metal patterning layer 212, so the electron injection layer 224 is formed on at least a portion of the organic material layer on which the metal patterning layer 212 is not formed.

The electron injection layer 224 may be formed of a material having high electrical conductivity, such as, but not limited to, a material selected from silver (Ag), magnesium (Mg), aluminum (Al), ytterbium (Yb), copper (Cu), zinc (Zn), cadmium (Cd), gold (Au), nickel (Ni), cobalt (Co), iron (Fe), molybdenum (Mo), niobium (Nb), palladium (Pd), platinum (Pt), lithium (Li), sodium (Na), calcium (Ca), and combinations thereof.

A light efficiency improvement layer 180 may be formed on one side of both sides of the first electrode 110 that is not in contact with the organic material layer, that is, on the side between the substrate and the first electrode 110, or on one side of both sides of the first portion 210 and the second portion 220 that is not in contact with the organic material layer, more specifically, on one side of both sides of the second electrode 222 and the metal patterning layer 212 that is not in contact with the organic material layer. FIG. 3 illustrates a case where the light efficiency improvement layer 180 is formed on one side of both sides of the second electrode 222 that is not in contact with the organic material layer.

By forming the light efficiency improvement layer, in the case of a top emission organic light emitting device, the optical energy loss due to SPPs (surface plasmon polaritons) at the second electrode can be reduced, and in the case of a bottom emission organic light emitting device, the light efficiency improvement layer can serve as a buffer between the first portion and the second portion.

According to another embodiment of the present invention, the organic material layer may be a form consisting of a plurality of stacks, wherein the stacks comprise a hole transport layer, a light-emitting layer, and an electron transport layer. This will be described with reference to FIG. 4.

FIG. 4 illustrates a laminated structure of an organic electric element according to another embodiment of the present invention.

Referring to FIG. 4, two or more sets of stacks of the organic material layers ST1 and ST2 may be formed between the first electrode 110 and the second electrode 170 in the organic electric element 300 according to another embodiment of the present invention, wherein the organic material layers are consisted of a plurity of layers, and the charge generation layer CGL may be formed between the stacks of the organic material layer.

Specifically, the organic electric element according to one embodiment of the present invention may comprise a first electrode 110, a first stack ST1, a charge generation layer CGL, a second stack ST2, and a second electrode 170 and a layer for improving light efficiency 180.

The first stack ST1 is an organic material layer formed on the first electrode 110, and the first stack ST1 may comprise the first hole injection layer 320, the first hole transport layer 330, the first light-emitting layer 340 and the first electron transport layer 350 and the second stack ST2 may comprise a second hole injection layer 420, a second hole transport layer 430, a second light-emitting layer 440 and a second electron transport layer 450. In this way, the first stack and the second stack may be organic material layers having the same laminated structure, or may also be organic material layers having different laminated structures.

The charge generation layer CGL may be formed between the first stack ST1 and the second stack ST2. The charge generation layer CGL may comprise a first charge generation layer 360 and a second charge generation layer 361. The charge generating layer CGL is formed between the first light-emitting layer 340 and the second light-emitting layer 440 to increase the current efficiency generated in each light-emitting layer and to smoothly distribute charges.

The first light-emitting layer 340 may comprise a light emitting material comprising a blue host doped with a blue fluorescent dopant and the second light-emitting layer 440 may comprise a light emitting material comprising a green host doped with a greenish yellow dopant and a red dopant together, but the material of the first light-emitting layer 340 and the second light-emitting layer 440 according to an embodiment of the present invention is not limited thereto.

In FIG. 4, n may be an integer of 1 to 5 and the charge generation layer CGL and the third stack may be further stacked on the second stack ST2 when n is 2.

When a plurality of light-emitting layers are formed in a multi-layer stack structure as shown in FIG. 4, it is possible to manufacture an organic electroluminescent element that emits not only white light but also various colors, wherein the white light is emitted by the mixing effect of light emitted from each light-emitting layer.

The charge generation layer may be formed of a n-and/or p-doped layer for injecting electrons and holes, and the electrons and holes may be supplied from the CGL and the electrodes, for example, but are not limited thereto, and may be selected from n and p conductive dopants.

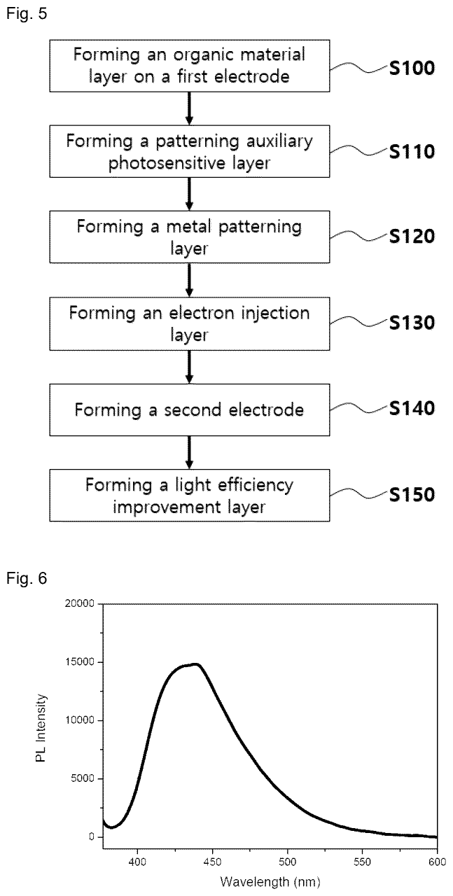

Hereinafter, a method for manufacturing an organic electric element according to one aspect of the present invention will be described with reference to FIG. 5. FIG. 5 is a drawing for explaining a method for manufacturing an organic electric element having the laminated structure of FIG. 3.

Referring to FIG. 3 and FIG. 5, first, an organic material layer is formed on the first electrode (S100).

The organic material layer is formed by sequentially depositing a hole injection layer 120, a hole transport layer 130, a light-emitting layer 140, an electron transport layer 150, etc. on the first electrode 110. As described above, at least one of these layers may be omitted, and an emission auxiliary layer, an electron transport auxiliary layer, etc. may be additionally formed.

The organic material layer may be manufactured using various deposition methods. For example, the material layer may be manufactured using a deposition method such as PVD (physical vapor deposition) or CVD (chemical vapor deposition). Further, the material layer may be manufactured in a smaller number of layers by methods such as solution process or solvent process, not deposition process, for example, spin coating, nozzle printing, inkjet printing, slot coating, dip coating, roll-to-roll, doctor blading, screen printing, or thermal transfer.

Preferably, the organic material layer may be formed by vacuum deposition. However, since the organic material layer according to the present invention may be formed by various methods, the scope of the present invention is not limited by the method forming the organic material layer.

Next, a patterning auxiliary photosensitive layer 214 is formed on the organic material layer (S110), and a material that suppresses the deposition of a metal material on the patterning auxiliary photosensitive layer 214 is vacuum-deposited to deposit a metal patterning layer 212 (S120).

Since the patterning auxiliary photosensitive layer 214 and the metal patterning layer 212 are formed on a part of the organic material layer, these layers may be vacuum-deposited on a desired area using a mask during the deposition process.

After forming the first portion 210 including the patterning auxiliary photosensitive layer 214 and the metal patterning layer 212, a metal material is vacuum-deposited to form an electron injection layer 224 (S130), and a second electrode 222 is formed on the electron injection layer 224 (S140).

The metal patterning layer 212 is formed of a material that suppresses the deposition of a metal material, i.e., a material that repels a metal material. Therefore, when the electron injection layer 224 and the second electrode 222 are deposited using a metal material, the metal material is repels from the metal patterning layer 212. Accordingly, the electron injection layer 224 and the second electrode 222, which is a metal electrode, are formed on at least a portion of the portion where the first portion 210 on the organic material layer is not formed, and these layers may be formed by vacuum deposition without using a mask.

Finally, a light efficiency improvement layer 180 is formed on the upper surface of the first portion 210 and the second portion 220 (S150).

An organic electric element according to one embodiment of the present invention may be a front-emitting, back-emitting, or double-sided emitting type depending on the material used.

In addition, the organic electric element according to one embodiment of the present invention may be selected from the group consisting of an organic electroluminescent element, an organic solar cell, an organic photo conductor, an organic transistor, an element for monochromatic illumination and an element for a quantum dot display.

Another embodiment of the present invention provides an electronic device including a display device which includes the above described organic electric element, and a control unit for controlling the display device. Here, the electronic device may be a wired/wireless communication terminal which is currently used or will be used in the future, and covers all kinds of electronic devices including a mobile communication terminal such as a cellular phone, a navigation unit, a game player, various kinds of TVs, and various kinds of computers. Preferably, the display device includes a transparent display, and the electronic device may include an Under Display Camera (UDC) or an Under Panel Sensor (UPS).

Hereinafter, the present invention will be described by way of examples. The following examples are intended to illustrate the present invention, and the scope of the rights of the present invention is not limited by these examples.

### Measurement of the Thickness of the Patterning Auxiliary Photosensitive Layer and the Metal Patterning Layer

### Comparative Example 1

A sample was fabricated by depositing a 10 nm metal patterning layer on a glass substrate.

### Comparative Example 2

The sample fabricated in Comparative Example 1 was exposed at atmospheric pressure and 85° C. for 10 hours.

### Comparative Example 3

A sample was fabricated by depositing a 50 nm metal patterning layer on a glass substrate.

### Comparative Example 4

The sample fabricated in Comparative Example 3 was exposed at atmospheric pressure and 85° C. for 10 hours.

### Examples 1 to Examples 5

A sample was fabricated by depositing a patterning auxiliary photosensitive layer on a glass substrate and then depositing a metal patterning layer.

The intensity of photoluminescence of the samples manufactured by Comparative Examples 1 to 4 and Examples 1 to 5 was measured using a RC2 XF Ellipsometer from J.A Woollam.

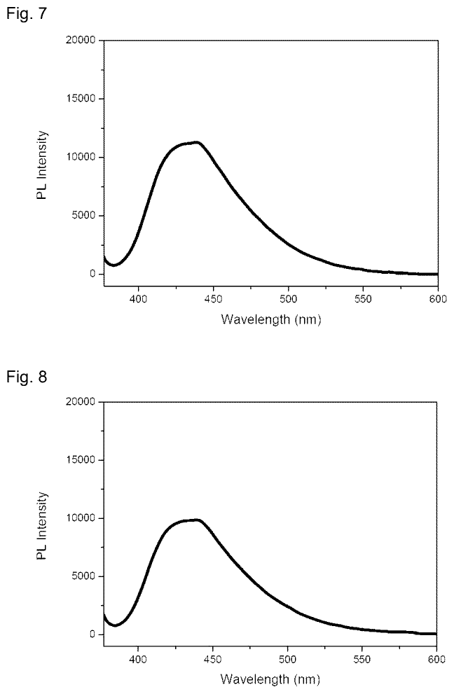

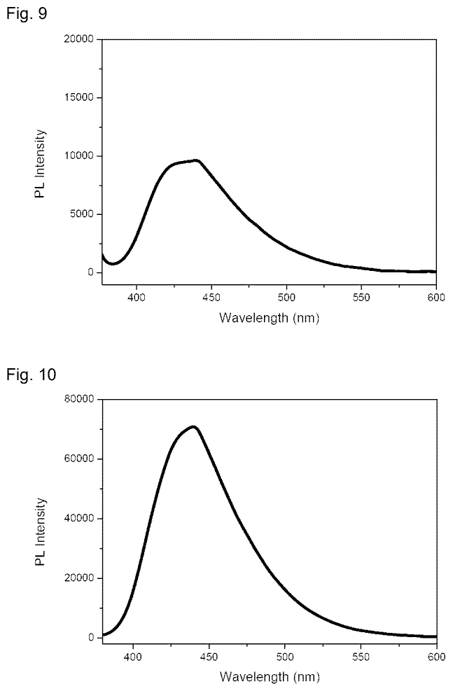

For Comparative Examples 1 to 4, the thickness of the metal patterning layer was measured using SEM, and for Examples 1 to 4, the thickness of the patterning auxiliary photosensitive layer and the metal patterning layer was measured using a RC2 XF Ellipsometer from J.A Woollam. The measurement results are as shown in Table 1 below, and the photoluminescence intensity according to the wavelength for each Example is as shown in FIGS. 6 to 10, and the photoluminescence intensity in Table 1 is written based on FIGS. 6 to 10.

TABLE 1

| | | Thickness | |
|---|---|---|---|
| | Thickness of the | of metal | |
| | patterning auxiliary | patterning | Intensity of |
| | photosensitive layer | layer | photoluminescence |
| classification | (nm) | (nm) | (a.u.) |
| Comparative | — | 10 | — |
| example 1 | | | |
| Comparative | — | 10 | — |
| example 2 | | | |
| Comparative | — | 50 | — |
| example 3 | | | |
| Comparative | — | 50 | — |
| example 4 | | | |
| Example 1 | 10 | 5 | 14618.59 |
| Example 2 | | 10 | 11295.04 |
| Example 3 | | 15 | 9848.39 |
| Example 4 | | 20 | 9643.12 |
| Example 5 | 90 | 90 | 71188.94 |

As can be seen in Table 1, for Comparative Examples 1 to 4 in which only the metal patterning layer was formed without forming a patterning auxiliary photosensitive layer, the intensity of photoluminescence could not be measured, whereas for Examples 1 to 5 in which a patterning auxiliary photosensitive layer was formed, the intensity of photoluminescence could be measured.

Therefore, the thickness was measured using a SEM in Comparative Examples 1 to 4 since the thickness of the metal patterning layer could not be measured using an Ellipsometer.

It was possible to measure the thickness of the patterning auxiliary photosensitive layer and the metal patterning layer using this for Examples 1 to 5 since the photoluminescence intensity was as shown in Table 1.

It can be seen that the photoluminescence intensity decreases when the thickness of the patterning auxiliary photosensitive layer is the same but the thickness of the metal patterning layer is different in examples 1 to 4. This is because the thicker the metal patterning layer, which has very weak PL characteristics or makes it difficult to measure the photoluminescence intensity, the smaller the thickness of the patterning auxiliary photosensitive layer with excellent PL characteristics. From this, it can be seen that the photoluminescence intensity may vary depending on the thickness of the patterning auxiliary photosensitive layer with excellent PL characteristics.

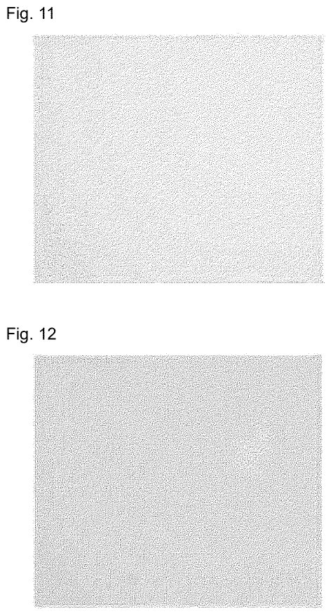

Meanwhile, the results of examining the thin films of samples of Comparative Examples 1 to 4 at 100× magnification using Nikon's Eclipse LV100ND are as shown in FIGS. 11 to 14.

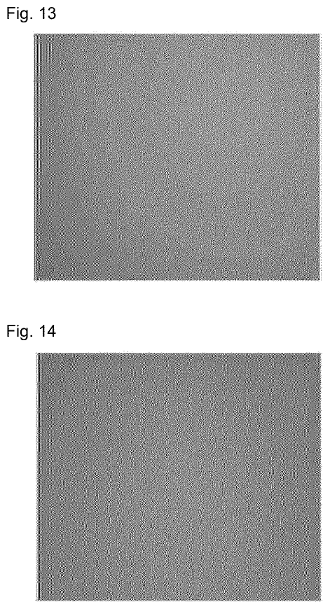

It can be seen that referring to FIGS. 11 and 13, when the metal patterning layer was checked immediately after sample production as in Comparative Examples 1 and 3, no particular difference was observed between the two samples, and referring to FIGS. 11 and 13, when the thin film is measured after aging for 10 hours after each sample is produced as in Comparative Examples 2 and 4, noise that is not found in Comparative Example 2 (FIG. 13) is confirmed in Comparative Example 4 (FIG. 14). This is because the thickness of the metal patterning layer is formed relatively thick, and the material formed on the metal patterning layer is aggregated, which was also confirmed in the optical microscope image.

In the case of a metal patterning layer, it is used as a layer applied to implement a transparent display, but if a coagulation phenomenon occurs as shown in FIG. 14, the transmittance may decrease, which may hinder the implementation of a high-quality transparent display.

In addition, when coagulation occurs in a thin film, there is a problem in that it is difficult to deposit an additional thin film on the thin film where coagulation occurred because the surface is uneven.

Therefore, it can be seen that it is essential to control the thickness of the metal patterning layer in order to implement a transparent display with high transmittance, and in order to appropriately control the thickness of the metal patterning layer, the thickness of the metal patterning layer can be measured relatively easily when a patterning auxiliary layer formed of a photosensitive material as in the present invention is formed,

### Verification of Accuracy of Film Thickness Measured Using an Ellipsometer

Additional experiments were conducted to verify that the thickness of each film measured using an Ellipsometer was accurate.

### Example 6

Experiment to check the thickness of the patterning auxiliary photosensitive layer and metal patterning layer using a scanning electron microscope (SEM)

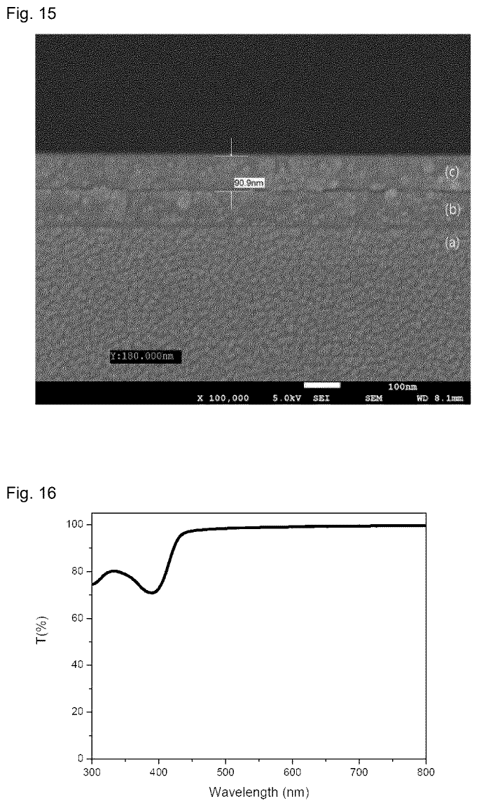

The thickness of the patterning auxiliary photosensitive layer and the metal patterning layer of the sample manufactured in Example 5 was checked using JEOL's JMS6701F. The results are as shown in FIG. 15.

In FIG. 15, (a) is a glass substrate, (b) is a patterning auxiliary photosensitive layer, and (c) is a metal patterning layer, and the thickness of the metal patterning layer was 90.9 nm. Therefore, it can be seen that the thickness of a metal patterning layer with low photoluminescence characteristics can be measured with a high level of accuracy by introducing a patterning auxiliary photosensitive layer.

### Experiment Comparing Light Transmittance According to the Presence or Absence of Patterning Auxiliary Photosensitive Layer

According to the present invention, the change in light transmittance depending on whether a patterning auxiliary photosensitive layer is introduced was measured.

### Example 7

A hole transport layer was formed on a glass substrate by vacuum deposition to a thickness of 100 nm, and then a patterning auxiliary photosensitive layer was formed on the hole transport layer by vacuum deposition to a thickness of 10 nm. Thereafter, a metal patterning layer was vacuum-deposited with a thickness of 10 nm on the patterning auxiliary photosensitive layer, Yb was vacuum-deposited to form an electron injection layer, and then Mg and Ag were deposited at a weight ratio of 1:9 to form a cathode. Thereafter, a light efficiency improvement layer with a thickness of 70 nm was formed on the cathode.

### Comparative Example 5

A sample was manufactured as in Example 7, except that the patterning auxiliary photosensitive layer was not formed.

### Comparative Example 6

A sample was manufactured as in Example 7, except that the patterning auxiliary photosensitive layer was not formed and the metal patterning layer was formed to a thickness of 50 nm.

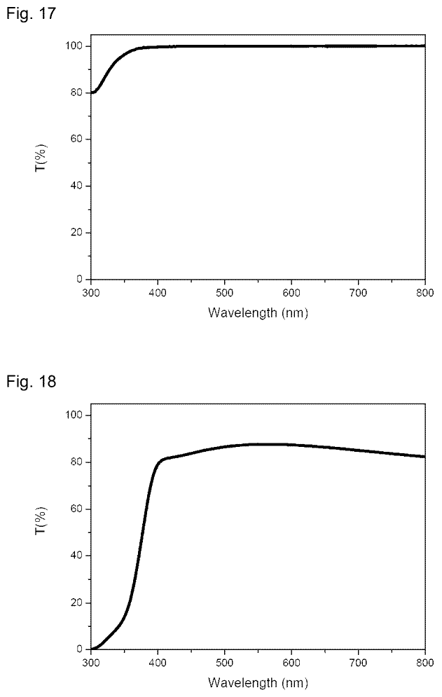

The light transmittance of the samples manufactured according to Example 7, Comparative Examples 2 and 3 was measured using a Lambda 365 UVIVIS Spectrometer from Perkinelmer. The results of measuring the light transmittance at 550 nm in the visible light range are shown in Table 2 below, and the light transmittance in Table 2 is based on the light transmittance graphs of FIGS. 16 to 18.

TABLE 2

| | | Thickness | |
|---|---|---|---|
| | Thickness of the | of metal | |
| | patterning auxiliary | patterning | Light |
| | photosensitive layer | layer | transmittance |
| classification | (nm) | (nm) | (%) |
| Example 7 | 10 | 10 | 98.86 |
| Comparative | — | 10 | 100 |
| example 5 | | | |
| Comparative | — | 50 | 87.69 |
| example 6 | | | |

From Table 2, it can be confirmed that even if a patterning auxiliary photosensitive layer is formed when the thickness of the metal patterning layer is 10 nm, the light transmittance is very excellent at 98.86%. Therefore, it can be seen that even if a patterning auxiliary photosensitive layer is formed under the metal patterning layer according to the present invention, there is no problem in implementing a transparent display.

Meanwhile, from Table 2, it can be seen that the light transmittance decreases when the thickness of the metal patterning layer is 50 nm, which appears to be due to the agglomeration phenomenon.

Therefore, it can be seen that it is necessary to control the thickness of the metal patterning layer when manufacturing an organic electric element, and according to the present invention, the thickness of the metal patterning layer can be easily measured.

That is, when a patterning auxiliary photosensitive layer having a photoluminescence characteristic in a visible light region is employed according to the present invention, the thickness of the metal patterning layer can be more easily controlled by utilizing the photoluminescence characteristics in the visible light range of the patterning auxiliary photosensitive layer without the introduction of a scanning electron microscope (SEM), which is realistically difficult to introduce in order to control the thickness of the metal patterning layer in the display manufacturing process, and it is possible to implement a transparent display with high light transmittance, and prevent problems such as performance degradation and additional thin film formation due to deviation in the deposition thickness of the material of the metal patterning layer in advance.

The above description is merely an example of the present invention, and those skilled in the art will appreciate that various modifications may be made without departing from the essential characteristics of the present invention. Accordingly, the embodiments disclosed in this specification are not intended to limit the present invention but to explain it, and the scope of the present invention is not limited by these embodiments. The scope of protection of the present invention should be interpreted by the following claims, and all techniques within a scope equivalent thereto should be interpreted as being included in the scope of the present invention.

What is claimed is:

1. An organic electric element comprising a metal patterning layer formed on the outside of a metal electrode and a patterning auxiliary photosensitive layer formed under the metal patterning layer, wherein the patterning auxiliary photosensitive layer is formed of a photosensitive organic material having a stronger intensity of photoluminescence than the metal patterning layer in the visible light range.

2. The organic electric element of claim 1, wherein the metal patterning layer comprises an organic material that suppresses deposition of a metal material.

3. The organic electric element of claim 1, wherein the patterning auxiliary photosensitive layer comprises a compound comprising at least one heterocycle.

4. The organic electric element of claim 3, wherein the heterocycle is a C₂-C₆₀ heterocycle containing at least one heteroatom of O, N, S, Si, and P.

5. The organic electric element of claim 3, wherein the compound forming the patterning auxiliary photosensitive layer has a molecular weight of 1,500 g/mol or less.

6. The organic electric element of claim 1, wherein the patterning auxiliary photosensitive layer is formed with a thickness of 5 nm or more.

7. The organic electric element of claim 1, wherein the patterning auxiliary photosensitive layer is formed by vacuum deposition.

8. The organic electric element of claim 1, wherein the metal patterning layer is formed of a compound containing fluorine.

9. The organic electric element of claim 1, wherein the metal electrode is selected from the group consisting of Ag, Mg, Al, Yb, Cu, Zn, Cd, Au, Ni, Co, Fe, Mo, Nb, Pd, Pt, Li, Na, Ca, and combinations thereof.

10. The organic electric element of claim 1, wherein the organic electric element comprises an organic material layer formed on an anode, and the patterning auxiliary photosensitive layer is formed on at least a portion of the organic material layer.

11. The organic electric element of claim 10, wherein the patterning auxiliary photosensitive layer is formed on the outer side of the metal electrode.

12. The organic electric element of claim 1, comprising a first portion and a second portion formed on an organic material layer, and wherein the first portion comprises the metal patterning layer and the patterning auxiliary photosensitive layer, and the second portion comprises the metal electrode.

13. The organic electric element of claim 12, wherein the second portion comprises an electron injection layer formed under the metal electrode.

14. The organic electric element of claim 12, wherein the first portion is a non-emissive region, and the second portion is emissive region.

15. The organic electric element of claim 12, wherein the first portion is a light-transmitting part, and the second portion is a non-light-transmitting part.

16. The organic electric element of claim 13, wherein the electron injection layer is formed with a material selected from the group consisting of Ag, Mg, Al, Yb, Cu, Zn, Cd, Au, Ni, Co, Fe, Mo, Nb, Pd, Pt, Li, Na, Ca, and combinations thereof.

17. The organic electric element of claim 10, further comprising a light efficiency improvement layer formed on one side of both sides of the metal electrode that is not in contact with the organic material layer, or on one side of both sides of the metal electrode and the metal patterning layer that is not in contact with the organic material layer.

18. The organic electric element of claim 10, wherein the organic material layer comprises a hole transport region, a light-emitting layer, and an electron transport region sequentially formed on the anode.

19. The organic electric element of claim 18, wherein the organic material layer comprises two or more stacks comprising the hole transport region, the light-emitting layer, and the electron transport region.

20. The organic electric element of claim 19, wherein the organic material layer further comprises a charge generation layer formed between the two or more stacks.

21. An electronic device comprising a display device and a control unit for driving the display device, wherein the display device comprises the organic electric element of claim 1.

22. The electronic device of claim 21, wherein the organic electric element is selected from the group consisting of an organic electroluminescent element, an organic solar cell, an organic photo conductor, an organic transistor, an element for monochromatic illumination and a quantum dot display.

23. The electronic device of claim 21, wherein the display device comprises a transparent display.
